(19) United States
(12) Patent Application Publication
(10) Pub. No.: US 2025/0212457 A1
(43) Pub. Date: Jun. 26, 2025

(54) RECESSED SOURCE/DRAIN EPITAXIAL STRUCTURE FOR DIRECT BACKSIDE CONTACT

(71) Applicant: QUALCOMM Incorporated, San Diego, CA (US)

(72) Inventors: Yan SUN, San Diego, CA (US); Shreesh NARASIMHA, Charlotte, NC (US)

(21) Appl. No.: 18/390,817

(22) Filed: Dec. 20, 2023

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/258

(57) ABSTRACT

A field effect transistor (FET) structure and method for making the same is disclosed. In an aspect, a FET structure comprises a gate structure disposed between first and second source/drain (S/D) structures. The gate structure comprises a vertical metal gate structure and a channel structure comprising a plurality of vertically-stacked, horizontal channels connecting the first and second S/D EPI structures horizontally through the vertical metal gate structure that at least partially surrounds the plurality of channels. At least one S/D structure comprises a lower portion that extends vertically below a bottom surface of the vertical metal gate structure, the lower portion comprising sides and a bottom surface. The FET structure also comprises frontside and backside inter-layer dielectric (ILD) layers respectively disposed above and below the vertical metal gate structure and the first and second S/D EPI structures.

### BACKGROUND OF THE DISCLOSURE

### 1. Field of the Disclosure

This disclosure relates generally to semiconductor wafer process, and more specifically to gate-all-around (GAA) field effect transistors (FETs) structures and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a field effect transistor (FET) structure includes a gate structure, disposed between a first source/drain (S/D) structure and a second S/D EPI structure, the gate structure comprising a channel structure and a vertical metal gate structure, the channel structure comprising a plurality of vertically-stacked, horizontal channels connecting the first S/D EPI structure to the second S/D EPI structure horizontally through the vertical metal gate structure that at least partially surrounds the plurality of channels, wherein at least one of the first S/D EPI structure and the second S/D EPI structure comprises a lower (recessed) portion that extends vertically below a bottom surface of the vertical metal gate structure, the lower portion comprising sides and a bottom surface; a frontside inter-layer dielectric (ILD) layer disposed above the vertical metal gate structure, the first S/D EPI structure, and the second S/D EPI structure; and a backside ILD layer disposed below the vertical metal gate structure, the first S/D EPI structure, and the second S/D EPI structure.

In an aspect, a method for fabricating a FET structure includes providing a gate structure, disposed between a first S/D EPI structure and a second S/D EPI structure, the gate structure comprising a channel structure and a vertical metal gate structure, the channel structure comprising a plurality of vertically-stacked, horizontal channels connecting the first S/D EPI structure to the second S/D EPI structure horizontally through the vertical metal gate structure that at least partially surrounds the plurality of channels, wherein at least one of the first S/D EPI structure and the second S/D EPI structure comprises a lower (recessed) portion that extends vertically below a bottom surface of the vertical metal gate structure, the lower portion comprising sides and a bottom surface; providing a frontside ILD layer disposed above the vertical metal gate structure, the first S/D EPI structure, and the second S/D EPI structure; and providing a backside ILD layer disposed below the vertical metal gate structure, the first S/D EPI structure, and the second S/D EPI structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIGS. 1A and 1B are top view and cross-sectional views, respectively, of a conventional semiconductor structure of an integrated circuit (IC) device with backside contacts.

FIGS. 2A and 2B are cross-sectional views of a semiconductor structure comprising a recessed source/drain (S/D) epitaxial (EPI) structure for direct backside contact, according to aspects of the disclosure.

FIGS. 3A-3O are cross-sections that illustrate steps in a process for fabricating a semiconductor structure having a recessed S/D EPI structure for direct backside contact, according to aspects of the disclosure.

FIG. 4 is a flowchart showing a portion of a simplified wafer process for fabricating a semiconductor structure having a recessed S/D EPI structure for direct backside contact, according to aspects of the disclosure.

FIGS. 5A-5N are cross-sections that illustrate steps in a process for fabricating a semiconductor structure having a recessed S/D EPI structure for direct backside contact, according to aspects of the disclosure.

FIG. 6 is a flowchart showing a portion of a simplified wafer process for fabricating a semiconductor structure having a recessed S/D EPI structure for direct backside contact, according to aspects of the disclosure.

FIG. 7 is a flowchart of an example process associated with recessed S/D EPI structures for direct backside contact, according to aspects of the disclosure.

FIG. 8 illustrates a mobile device in accordance with some examples of the disclosure.

FIG. 9 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Afield effect transistor (FET) structure having recessed source/drain (S/D) epitaxial (EPI) structures for direct backside contact and methods for making the same are disclosed. In an aspect, a FET structure comprises a gate structure disposed between first and second S/D EPI structures. The gate structure comprises a vertical metal gate structure and a channel structure comprising a plurality of vertically-stacked, horizontal channels connecting the first and second S/D EPI structures horizontally through the vertical metal gate structure that at least partially surrounds the plurality of channels. Each S/D EPI structure comprises a lower portion that extends vertically below a bottom surface of the vertical metal gate structure, the lower portion comprising sides and a bottom surface, and are therefore referred to herein as recessed S/D EPI structures. The FET structure also comprises a frontside inter-layer dielectric (ILD) layer disposed above the vertical metal gate structure and the first and second S/D EPI structures, and a backside ILD layer disposed below the vertical metal gate structure and the first and second S/D EPI structures.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Particular aspects of the subject matter described in this disclosure can be implemented to realize one or more of the following potential advantages. Because the recessed S/D EPI structures extend below the gate structures, backside contacts are far enough away from the gate structures that there is less chance that a process error (e.g., an etch process that etched too deep, a lithography process that was not completely aligned to the wafer, etc.) will cause the backside contact to short circuit with the gate. Also, since the contact does not have to fit solely within the space between adjacent gates, a backside contact can be made with a larger surface area, which reduces contact resistance.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

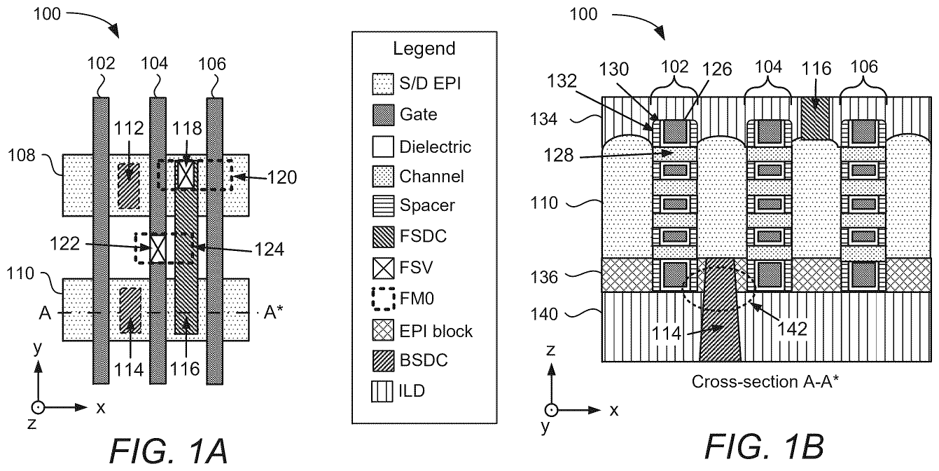

FIG. 1A is a top view of a portion of a semiconductor structure 100 of a conventional integrated circuit (IC) device with backside power. In some aspects, FIG. 1A merely shows some elements of the semiconductor structure 100 for illustration purposes, and other elements above and/or below the elements shown in FIG. 1A may be disposed but not shown in FIG. 1A. As shown in FIG. 1A, the semiconductor structure 100 includes gate stacks 102, 104, and 106 spaced along a first direction (e.g., the x direction) and having a length along a second direction (e.g., the y direction). As used herein, the term “gate stack” refers to a structure that includes a metal gate and which may also include dielectric material, an inner spacer, and other structural components. As used herein, the terms “gate” and “gate stack” are synonymous unless specifically indicated as otherwise. The semiconductor structure 100 also includes a first region 108 of epitaxial (EPI) source/drain (S/D) structures between the gate stacks and a second region 110 of EPI S/D structures between the gate stacks. The semiconductor structure 100 also includes a first backside S/D contact (BSDC) 112 and a second BSDC 114. The semiconductor structure 100 also includes a frontside S/D contact (FSDC) 116. A frontside via (FSV) 118 electrically connects the FSDC 116 to a first frontside metal zero (FM0) structure 120. Another FSV 122 electrically connects the gate stack 104 to a second FM0 structure 124.

FIG. 1B is a cross-sectional view of the semiconductor structure 100 along cut-line A-A*. As can be seen in FIG. 1B, each gate cross-section includes a metal gate structure 126 through which one or more channels 128 extend, insulated from the gate metal by a dielectric 130 and insulated from the EPI structures by an inner spacer 132. As shown in FIG. 1B, a top inter-layer dielectric (ILD) layer 134 covers the tops of the gate stacks and EPI regions. It is through this top ILD layer 134 that the FSDC 116 extends. As shown in FIG. 1B, an EPI block or etch stop layer 136 surrounds the bottom portion of each gate, and a bottom ILD layer 140 covers the bottoms of the gate stacks and the etch stop layer 136. It is through this bottom ILD layer 140 that the BSDC 114 extends. FIG. 1B also illustrates a disadvantage of this conventional structure—namely, that patterning steps (mask, etch, etc.) to create the BSDC 114 must be precise enough so that the BSDC 114 does not unintentionally make contact with the gate stacks on either side, e.g., in the area labeled 142 in FIG. 1B. To ensure that this does not happen, conventional processes constrain the side-to-side dimensions of BSDCs, which result in smaller BSDCs with higher resistance. These constraints also are a barrier to reduction of layout size, since the BSDC 114 and the gate stacks on either side would get even closer to each other as the chip dimensions are scaled down.

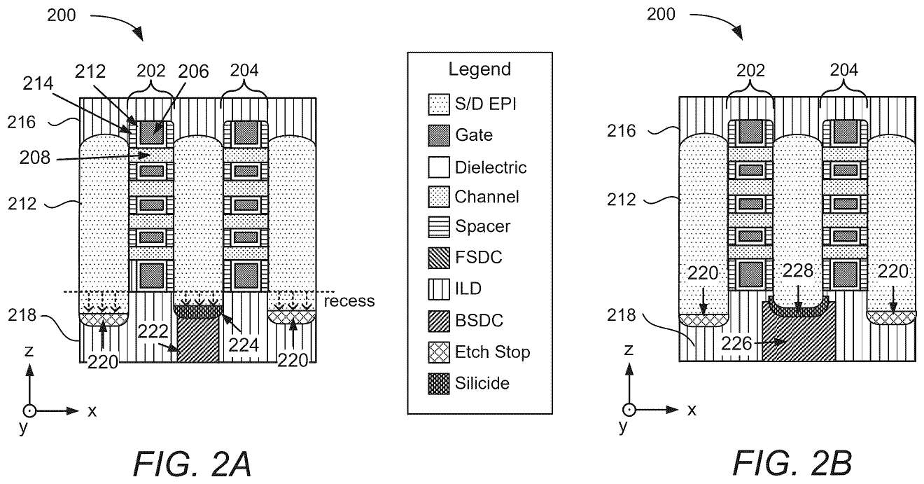

FIG. 2A and FIG. 2B are cross-sectional views of a semiconductor structure 200 comprising a recessed source/drain epitaxial structure for direct backside contact, according to aspects of the disclosure. Each of FIG. 2A and FIG. 2B shows a cross-section of gate stack 202 and gate stack 204. As can be seen in FIG. 2A and FIG. 2B, each gate stack cross-section includes a metal gate structure 206 through which one or more channels 208 extend, insulated from the gate metal by a dielectric 210 and insulated from the EPI structures 212 by an inner spacer 214. As shown in FIG. 2A, a top ILD layer 216 covers the tops of the gate stacks and EPI structures, and a bottom ILD layer 218 covers the bottoms of the gate stacks and the EPI structures. As shown in FIGS. 2A and 2B, however, the EPI structures 212 are recessed, i.e., they extend below the bottoms of the gate stacks, terminating at an etch stop layer 220 during fabrication. As a result, the process to etch a hole in the bottom ILD layer 218 for the later deposition of a BSDC 222 does not need to be so accurate, since the BSDC 222 is not close to the bottom of the gate stacks 202 and 204. A silicide structure 224, which replaces the existing etch stop layer 220 at that location during fabrication, provides an interface between the BSDC 222 and the EPI structure 212.

An advantage to using the recessed S/D EPI structures shown in FIGS. 2A and 2B is that the BSDC 222 can be the full width of the EPI structure, which increases the contact area between the BSDC 222 and the EPI structure and reduces contact resistance. As shown in FIG. 2B, the BSDC 226 and silicide structure 228 may even be oversized, i.e., larger than the width of the EPI structure. This may result in a BSDC 226 and silicide structure 228 that wrap around the sides of the portion of the EPI structure that extends below the gate stacks, further increasing the contact area and further reducing the contact resistance.

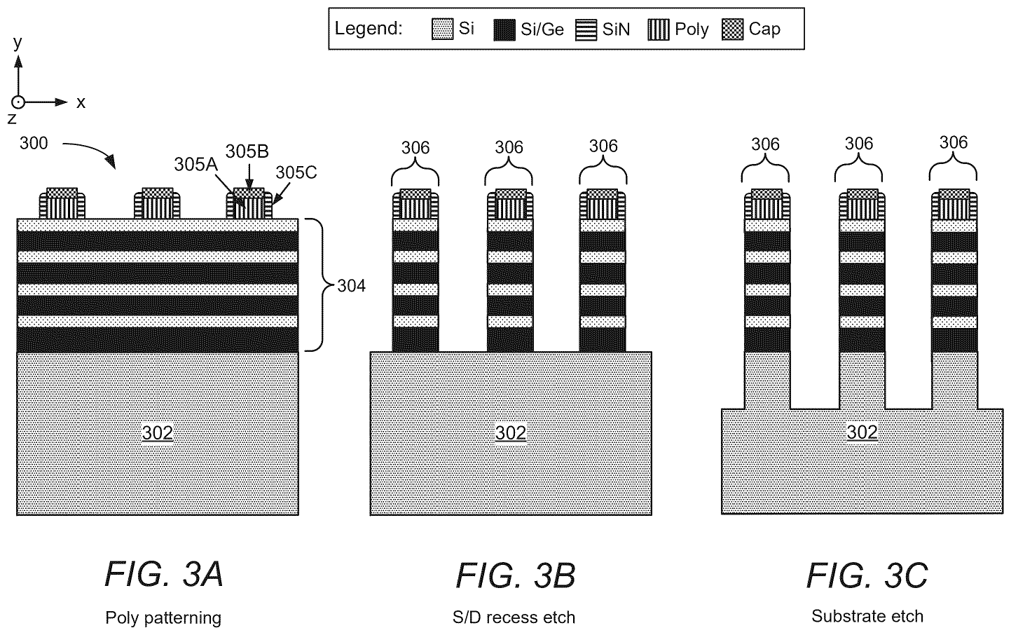

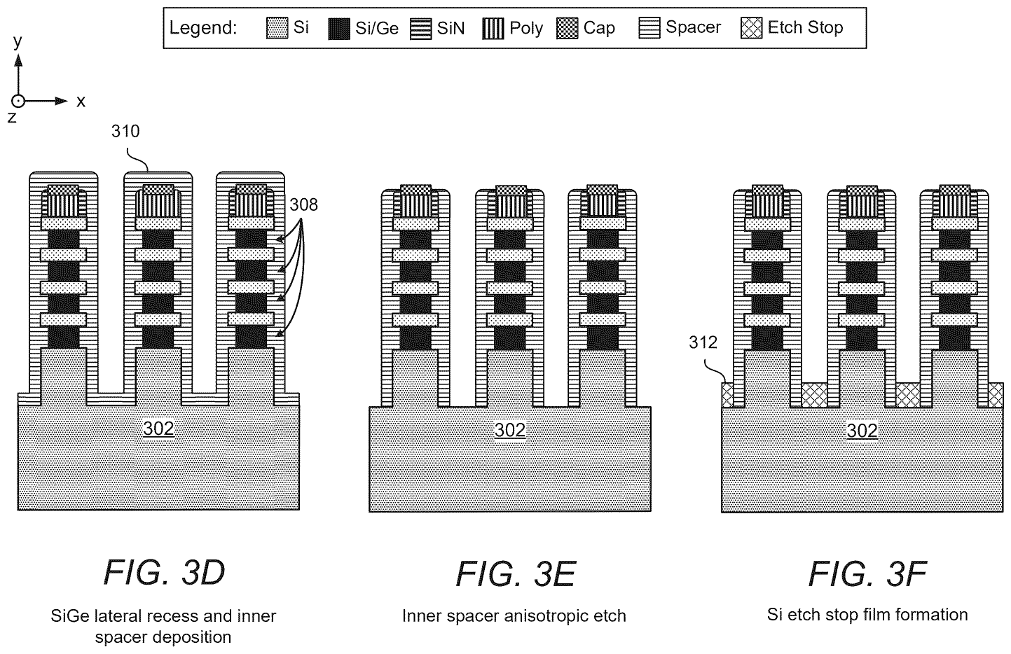

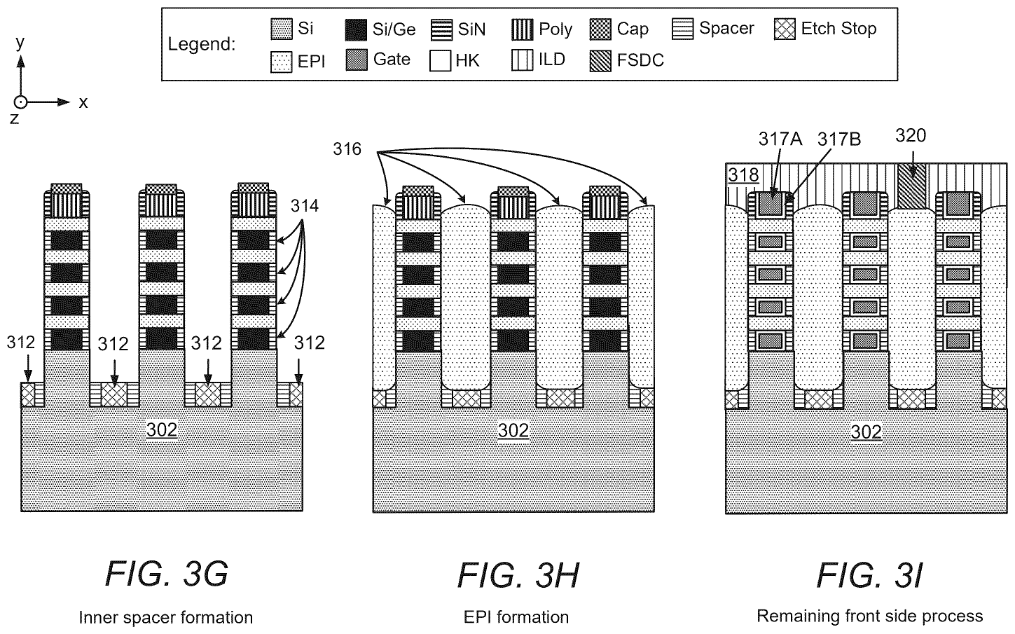

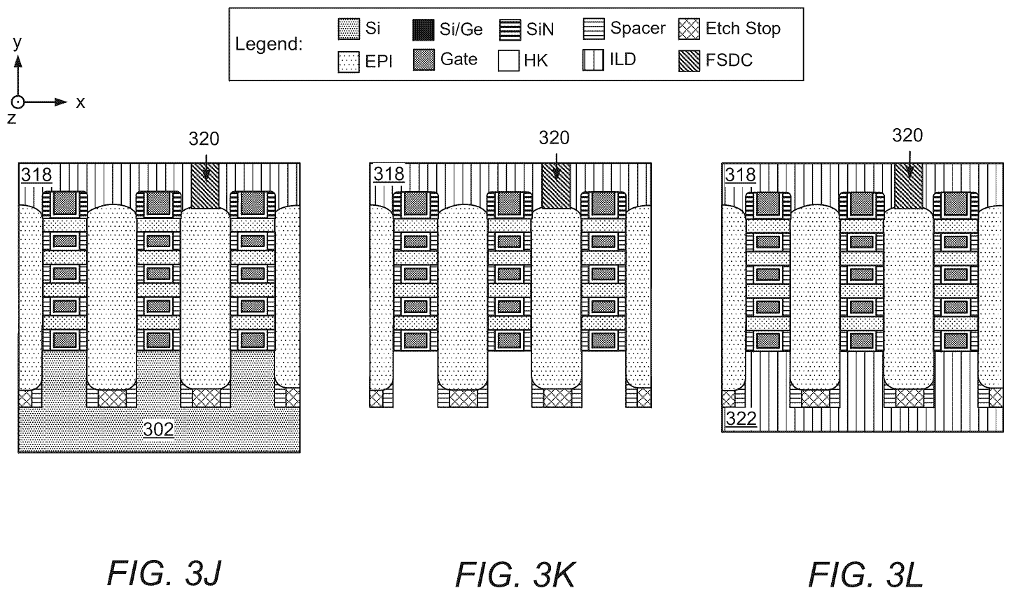

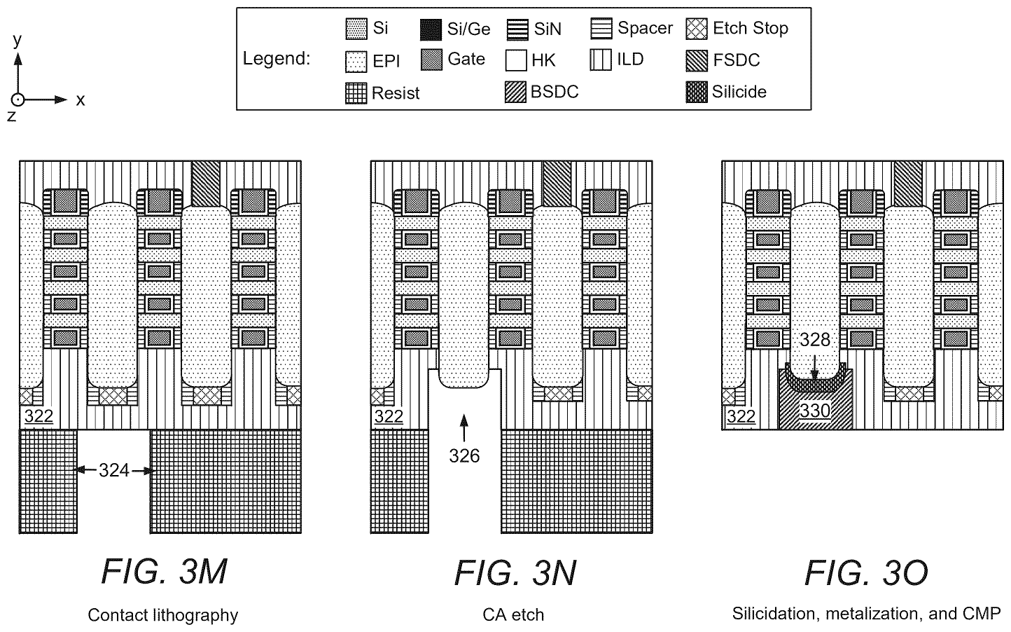

FIGS. 3A-3O are cross-sections that illustrate steps in a process for fabricating a semiconductor structure having a recessed S/D EPI structure for direct backside contact, according to aspects of the disclosure. As shown in FIG. 3A, the process starts with a semiconductor structure 300 comprising a silicon substrate 302 upon which have been fabricated alternating layers 304 of silicon (Si) and silicon/germanium (Si/Ge).

FIG. 3A illustrates the result after application of a polysilicon (“poly”) patterning step that is the basis for a self-aligned gate fabrication process. The poly patterning step creates structures comprising a polysilicon structure 305A topped with a cap structure 305B (e.g., a dielectric material) and flanked by sidewall spacers 305C (e.g., silicon nitride (SiN)).

FIG. 3B illustrates the result after source/drain (S/D) etching process that etches through the alternating layers 304 to form recesses in which S/D EPI will later be grown.

FIG. 3C illustrates the result after a substrate etching process that etches recesses into the substrate 302.

FIG. 3D illustrates the result after a process to create lateral recesses 308 in each gate stack and to deposit an inner spacer material 310.

FIG. 3E illustrates the result after an anisotropic etch process that removes the inner spacer material 310 from the bottom of each recess and from the top of the gate stacks.

FIG. 3F illustrates the result after deposition of an etch stop film 312 at the bottom of each recess. Materials that can be used for the etch stop film 312 include, but are not limited to, titanium silicide (TiSi), silicon carbon nitride (SiCN), silicon carbon oxynitride (SiCON), aluminum nitride (AlN), area-selective deposition (ASD) dielectrics, SiGe EPI, and other materials that have high etch selectivity to spacer and later backside Si removal.

FIG. 3G illustrates the result after an isotropic etch process that leaves the inner spacers 314.

FIG. 3H illustrates the result after an EPI formation process, resulting in EPI structures 316 that extend down to the etch stop film at the bottom of each recess.

FIG. 3I illustrates the result after completion of the remaining steps of the front side process. This includes forming the gate metal 317A and high-K dielectric 317B structures, deposition of a top ILD layer 318, and creation of an FSDC 320.

FIG. 3J illustrates the result after a substrate thin-down process in which the bulk of the substrate 302 is removed.

FIG. 3K illustrates the result after a process for fully removing the substrate 302, e.g., via an anisotropic etch and wet clean.

FIG. 3L illustrates the result after depositing a bottom ILD 322 and performing a chemical/mechanical polishing (CMP) step.

FIG. 3M illustrates the result after a contact lithography process that creates a resist layer 324.

FIG. 3N illustrates the result after a contact etch process that creates a BSDC recess 326.

FIG. 3O illustrates the result after a process that deposits silicide 328 and a BSDC 330 into the BSDC recess 326, followed by CMP.

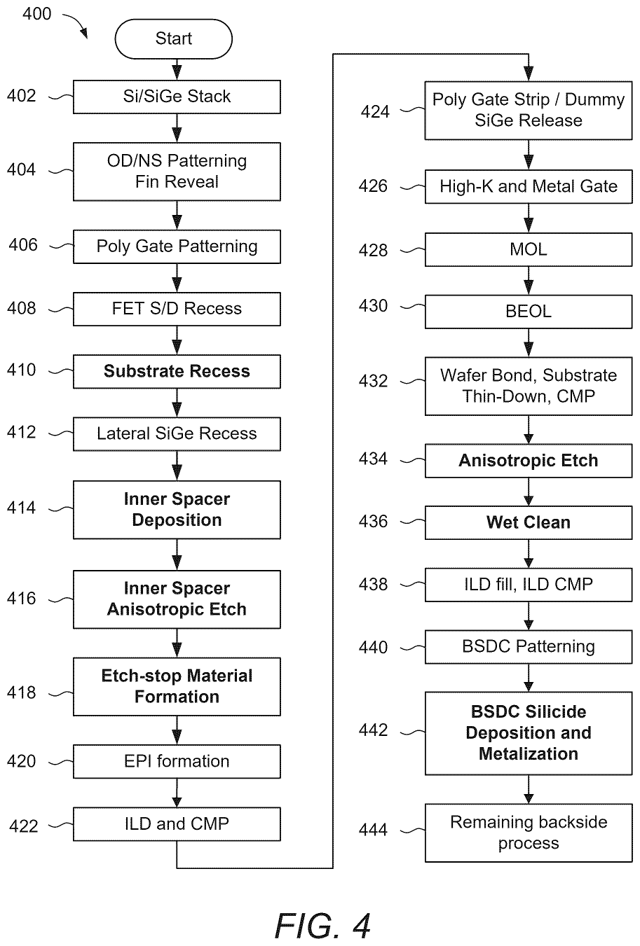

FIG. 4 is a flowchart showing a portion of a simplified wafer process for fabricating a semiconductor structure having a recessed S/D EPI structure for direct backside contact, according to aspects of the disclosure. As shown in FIG. 4, the process 400 may include, at block 402, forming the Si/SiGe stack, e.g., the alternating layers 304 in FIG. 3A.

The process 400 may include, at block 404, performing oxide diffusion/nanosheet patterning and fin reveal, and at block 406, polysilicon gate patterning, e.g., to produce the structures shown on the top surface of the alternating layers 304 in FIG. 3A.

The process 400 may include, at block 408, creating FET S/D recesses, e.g., by etching the alternating layers 304 to create gate stacks 306 with recesses between them, as shown in FIG. 3B.

The process 400 may include, at block 410, creating substrate recesses, e.g., by etching between the gate stacks 306 to create recesses in the substrate 302, as shown in FIG. 3C.

The process 400 may include, at block 412, creating lateral SiGe recesses, e.g., the lateral recesses 308 in the SiGe layers as shown in FIG. 3D.

The process 400 may include, at block 414, deposition of an inner spacer, e.g., the inner spacer material 310 in FIG. 3D.

The process 400 may include, at block 416, an inner spacer anisotropic etch to remove the inner spacer material from the bottom of the S/D recesses, as shown in FIG. 3E.

The process 400 may include, at block 418, formation of etch stop material at the bottom of the S/D recesses, as shown in FIG. 3F, followed by an isotropic etch for inner spacer formation, as shown in FIG. 3G.

The process 400 may include, at block 420, formation of EPI structures, e.g., EPI structures 316 as shown in FIG. 3H.

The process 400 may include, at block 422, deposition of ILD followed by CMP, e.g., as shown in FIG. 3I.

The process 400 may include, at block 424, performing a poly gate strip and dummy SiGe release process.

The process 400 may include, at block 426, a high-K dielectric and metal gate process.

The process 400 may include, at block 428, performing a middle-of-line (MOL) process.

The process 400 may include, at block 430, performing a back-end-of-line (BEOL) process, which completes the frontend process steps.

The process 400 may include, at block 432, bonding the structure to a carrier wafer, flipping the structure, and performing a substrate thin-down process followed by CMP, e.g., as shown in FIG. 3J.

The process 400 may include, at block 434, an anisotropic etch process, and at block 436, a wet clean process, e.g., as shown in FIG. 3K.

The process 400 may include, at block 438, an ILD fill and ILD CMP process, e.g., as shown in FIG. 3L.

The process 400 may include, at block 440, a BSDC patterning step, e.g., as shown in FIG. 3M (resist) and FIG. 3N (etch).

The process 400 may include, at block 442, a BSDC silicide deposition process followed by a BSDC metallization process, e.g., as shown in FIG. 3O.

The process 400 may include, at block 444, performing the remaining steps of the backside process.

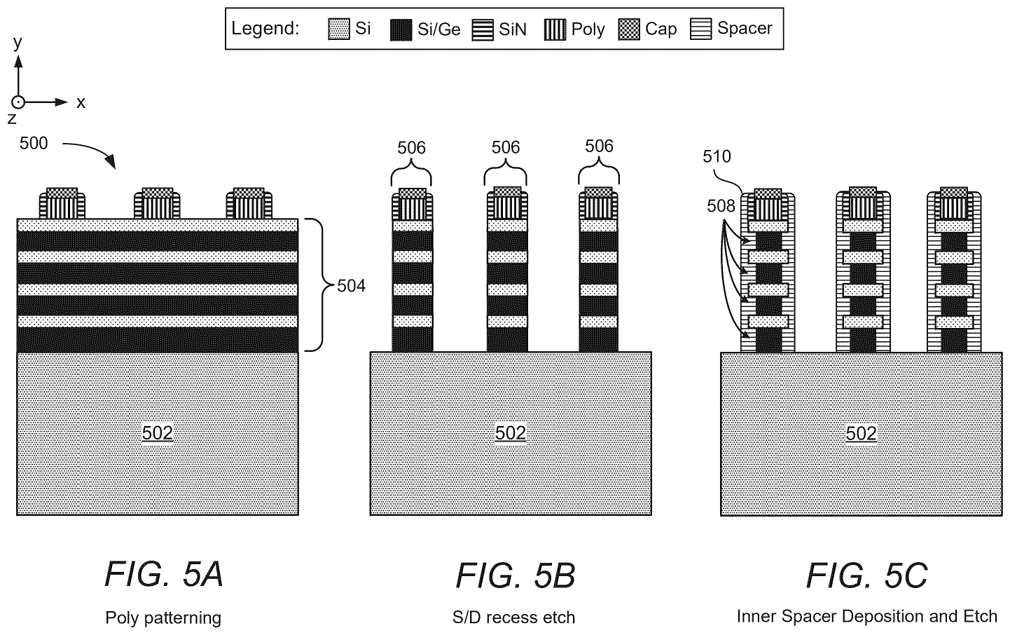

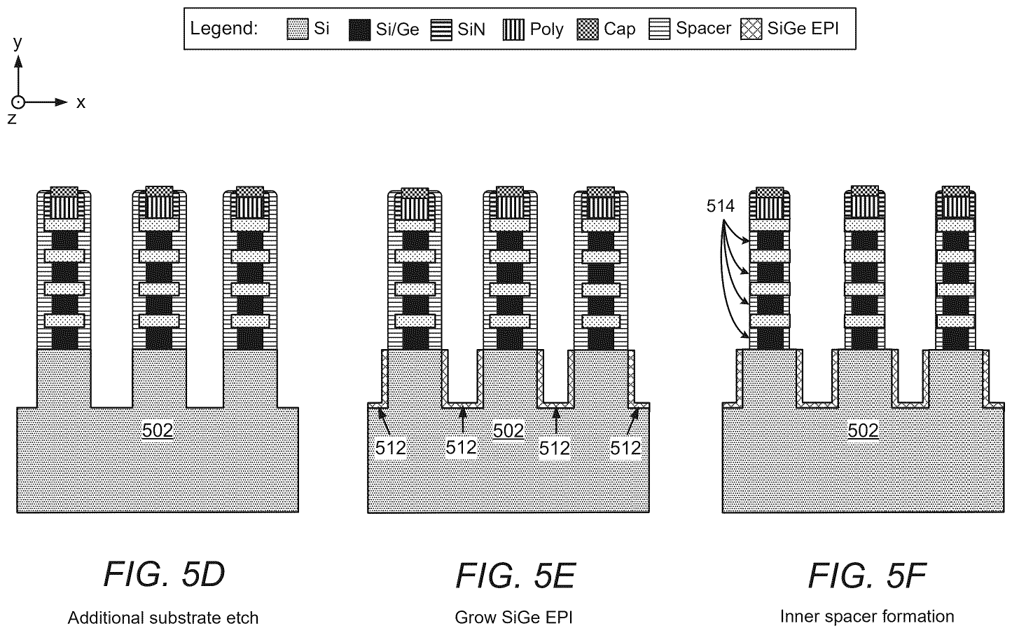

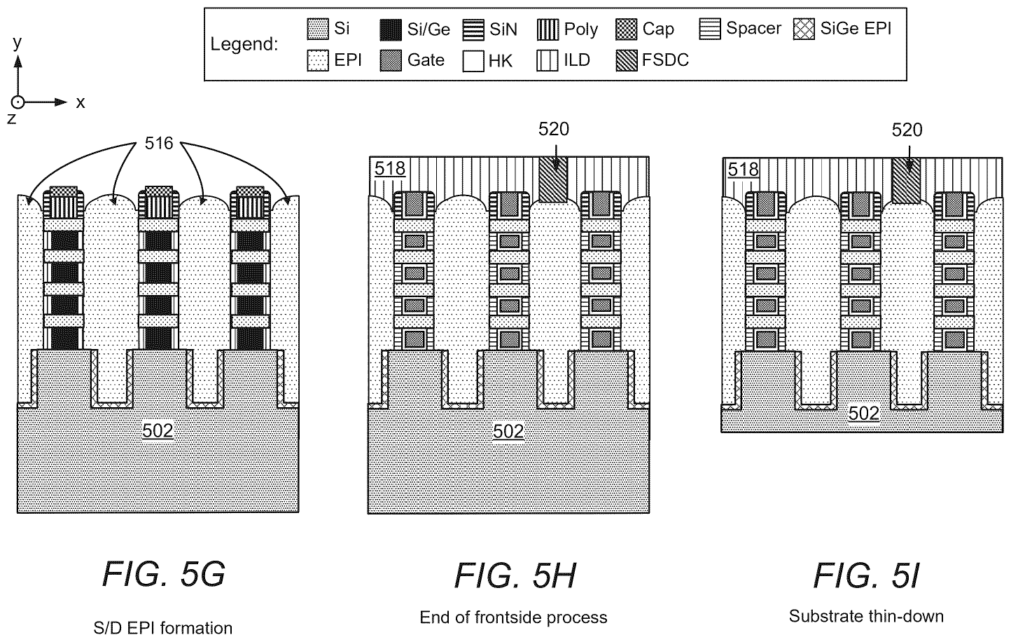

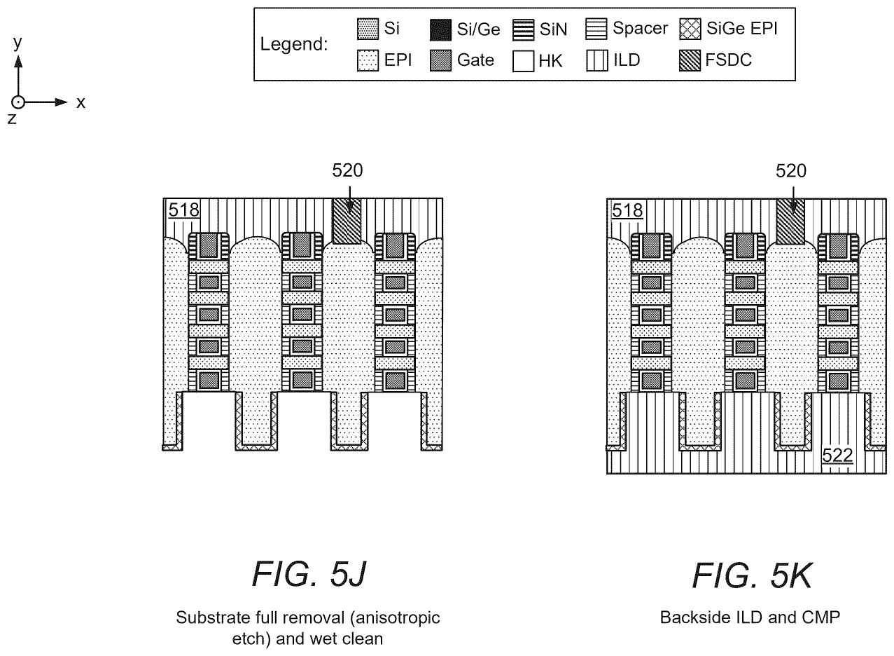

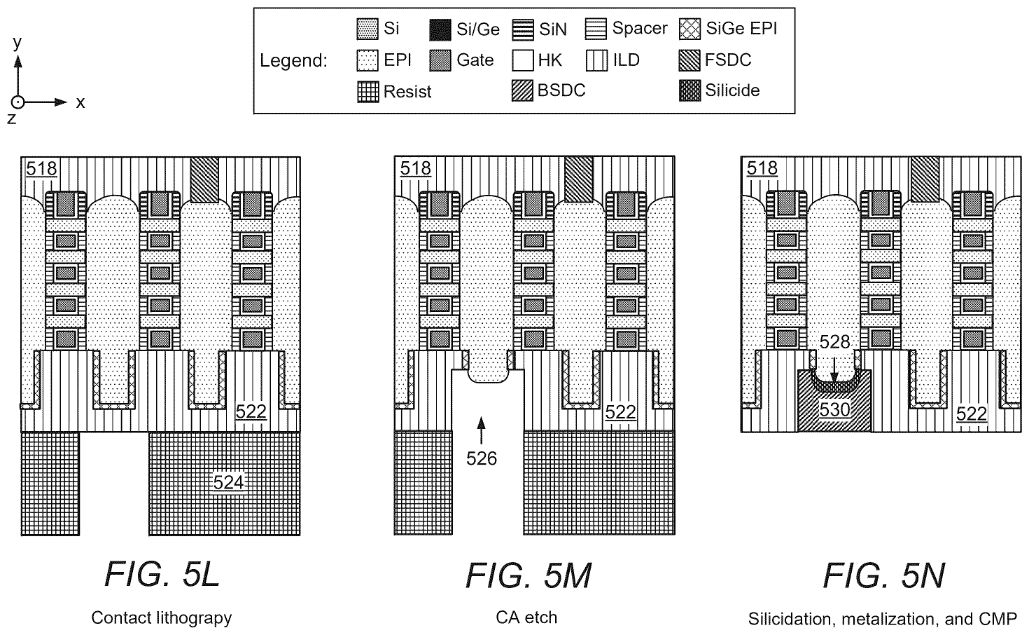

FIGS. 5A-5N are cross-sections that illustrate steps in a process for fabricating a semiconductor structure having a recessed S/D EPI structure for direct backside contact, according to aspects of the disclosure. As shown in FIG. 5A, the process starts with a semiconductor structure 500 comprising a substrate 502 (e.g., silicon) upon which have been fabricated alternating layers 504 of silicon (Si) and silicon/germanium (Si/Ge).

FIG. 5A illustrates the result after application of a polysilicon (“poly”) patterning step that is the basis for a self-aligned gate fabrication process.

FIG. 5B illustrates the result after source/drain (S/D) etching process that etches through the alternating layers 504 to form recesses in which S/D EPI will later be grown.

FIG. 5C illustrates the result after a process to create lateral recesses 508 in each gate stack and to deposit an inner spacer material 510.

FIG. 5D illustrates the result after a substrate etching process that etches recesses into the substrate 502.

FIG. 5E illustrates the result after growth of a etch stop film 512 on the exposed portions of the substrate 502 within each recess. Materials that can be used for the etch stop film 512 include, but are not limited to, titanium silicide (TiSi), silicon carbon nitride (SiCN), silicon carbon oxynitride (SiCON), aluminum nitride (AlN), area-selective deposition (ASD) dielectrics, SiGe EPI, and other materials that have high etch selectivity to spacer and later backside Si removal.

FIG. 5F illustrates the result after an isotropic etch process that leaves the inner spacers 514.

FIG. 5G illustrates the result after an EPI formation process, resulting in EPI structures 516 that extend down to the etch stop film at the bottom of each recess.

FIG. 5H illustrates the result after completion of the remaining steps of the frontside process. This includes forming the gate metal and dielectric structures, deposition of a top ILD layer 518, and creation of an FSDC 520.

FIG. 5I illustrates the result after a substrate thin-down process in which the bulk of the substrate 502 is removed.

FIG. 5J illustrates the result after a process for fully removing the substrate 502, e.g., via an anisotropic etch and wet clean.

FIG. 5K illustrates the result after depositing a bottom ILD layer 522 and performing a chemical/mechanical polishing (CMP) step.

FIG. 5L illustrates the result after a contact lithography process that creates a resist layer 524.

FIG. 5M illustrates the result after a contact etch process that creates a BSDC hole 526.

FIG. 5N illustrates the result after a process that deposits silicide 528 and a BSDC 530 into the BSDC hole 526, followed by CMP.

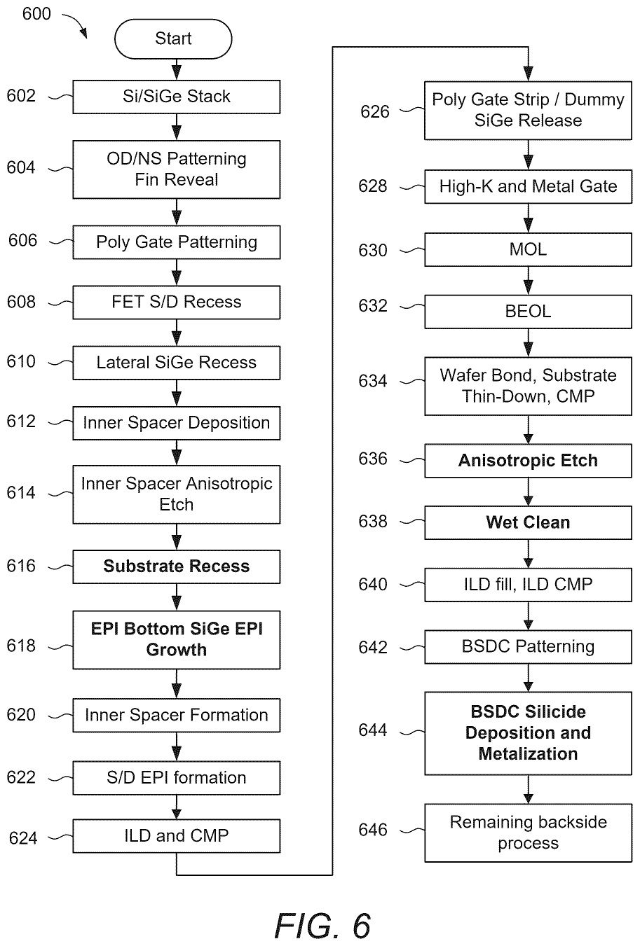

FIG. 6 is a flowchart showing a portion of a simplified wafer process for fabricating the structures shown in FIGS. 5A-5N, according to aspects of the disclosure. As shown in FIG. 6, the process 600 may include, at block 602, forming the Si/SiGe stack, e.g., the alternating layers 304 in FIG. 3A.

The process 600 may include, at block 604, performing OD/NS patterning and fin reveal, and at block 606, polysilicon gate patterning, e.g., to produce the structures shown on the top surface of the alternating layers 504 in FIG. 5A.

The process 600 may include, at block 608, creating FET S/D recesses, e.g., by etching the alternating layers 504 to create gate stacks 506 with recesses between them, as shown in FIG. 5B.

The process 600 may include, at block 610, creating lateral SiGe recesses, e.g., the lateral recesses 508 in the SiGe layers as shown in FIG. 5C.

The process 600 and may include, at block 612, deposition of an inner spacer, and, at block 614, an inner spacer anisotropic etch to remove the inner spacer material from the bottom of the S/D recesses, e.g., to produce the inner spacer material 510 in FIG. 5C.

The process 600 may include, at block 616, creating substrate recesses, e.g., by etching between the gate stacks 506 to create recesses in the substrate 502, as shown in FIG. 5D.

The process 600 may include, at block 618, EPI bottom SiGe EPI growth, e.g., to create the etch stop film 512 shown in FIG. 5E.

The process 600 may include, at block 620, an anisotropic etch for inner spacer formation, e.g., that results in the inner spacers 514 shown in FIG. 5F.

The process 600 may include, at block 622, formation of S/D EPI structures, e.g., EPI structures 516 as shown in FIG. 5G.

The process 600 may include, at block 624, deposition of ILD followed by CMP, e.g., to create the top ILD layer 518 as shown in FIG. 5H.

The process 600 may include, at block 626, performing a poly gate strip and dummy SiGe release process, and at block 628, a high-K dielectric and metal gate process, e.g., to produce the gate stacks shown in FIG. 5H. Example processes include a replacement metal gate (RMG) process that includes removing the cap structures 305B, removing the poly structures 305A, selectively removing the SiGe layers 304 while leaving the Si layers 304, depositing the high-K dielectric 317B on the exposed Si layers 304, and filling the space formerly occupied by the SiGe with metal 317A, which surrounds the high-K dielectric 317B and forms a vertical metal gate.

The process 600 may include, at block 630, performing a middle-of-line (MOL) process, and, at block 632, performing a back-end-of-line (BEOL) process, which completes the frontend process steps.

The process 600 may include, at block 634, bonding the structure to a carrier wafer, flipping the structure, and performing a substrate thin-down process followed by CMP, e.g., as shown in FIG. 5I.

The process 600 may include, at block 636, an anisotropic etch process, and at block 638, a wet clean process, e.g., as shown in FIG. 5J.

The process 600 may include, at block 640, an ILD fill and ILD CMP process, e.g., to create the bottom ILD layer 522 as shown in FIG. 5K.

The process 600 may include, at block 642, a BSDC patterning step, e.g., as shown in FIG. 5L (resist) and FIG. 5M (etch).

The process 600 may include, at block 644, a BSDC silicide deposition process followed by a BSDC metallization and CMP process, e.g., as shown in FIG. 5N.

The process 600 may include, at block 646, performing the remaining steps of the backside process.

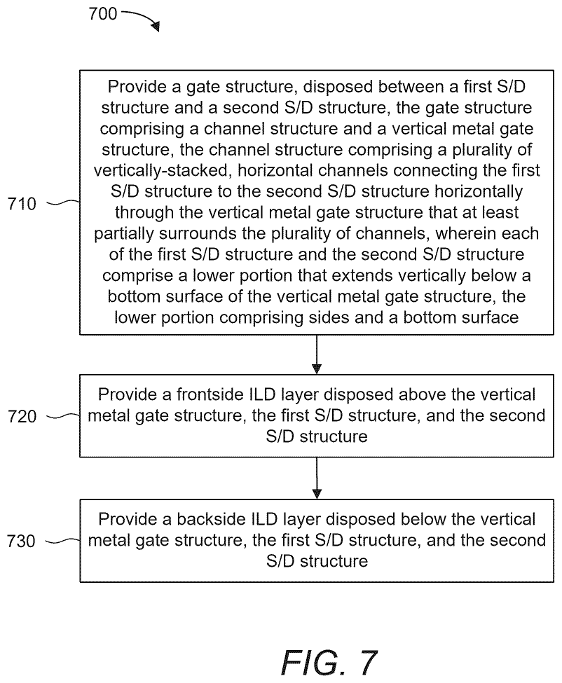

FIG. 7 is a flowchart of an example process 700 associated with recessed S/D EPI structures for direct backside contact, according to aspects of the disclosure.

As shown in FIG. 7, process 700 may include, at block 710, providing a gate structure, disposed between a first S/D EPI structure and a second S/D EPI structure, the gate structure comprising a channel structure and a vertical metal gate structure, the channel structure comprising a plurality of vertically-stacked, horizontal channels connecting the first S/D EPI structure to the second S/D EPI structure horizontally through the vertical metal gate structure that at least partially surrounds the plurality of channels, wherein at least one of the first S/D EPI structure and the second S/D EPI structure comprises a lower portion that extends vertically below a bottom surface of the vertical metal gate structure, the lower portion comprising sides and a bottom surface.

As further shown in FIG. 7, process 700 may include, at block 720, providing a frontside inter-layer dielectric (ILD) layer disposed above the vertical metal gate structure, the first S/D EPI structure, and the second S/D EPI structure.

As further shown in FIG. 7, process 700 may include, at block 730, providing a backside ILD layer disposed below the vertical metal gate structure, the first S/D EPI structure, and the second S/D EPI structure.

In some aspects, process 700 includes providing a first coupling material disposed on the bottom surface of the lower portion of the first S/D EPI structure, and providing a first backside S/D contact (BSDC) extending vertically through the backside ILD layer and in contact with the first coupling material. In some aspects, the first coupling material comprises silicide. Examples of coupling materials include, but are not limited to, nickel silicide, titanium silicide, molybdenum silicide, and tungsten silicide.

In some aspects, the first coupling material is further disposed on at least one of the sides of the lower portion of the first S/D EPI structure.

In some aspects, process 700 includes providing a first etch stop material disposed on at least the bottom surface of the lower portion of the second S/D EPI structure. In some aspects, the first etch stop material is further disposed on at least one of the sides of the lower portion of the second S/D EPI structure. In some aspects, the first etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

In some aspects, the gate structure comprises a gate-all-around (GAA) structure.

Process 700 may include additional implementations, such as any single implementation or any combination of implementations described below and/or in connection with one or more other processes described elsewhere herein. Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

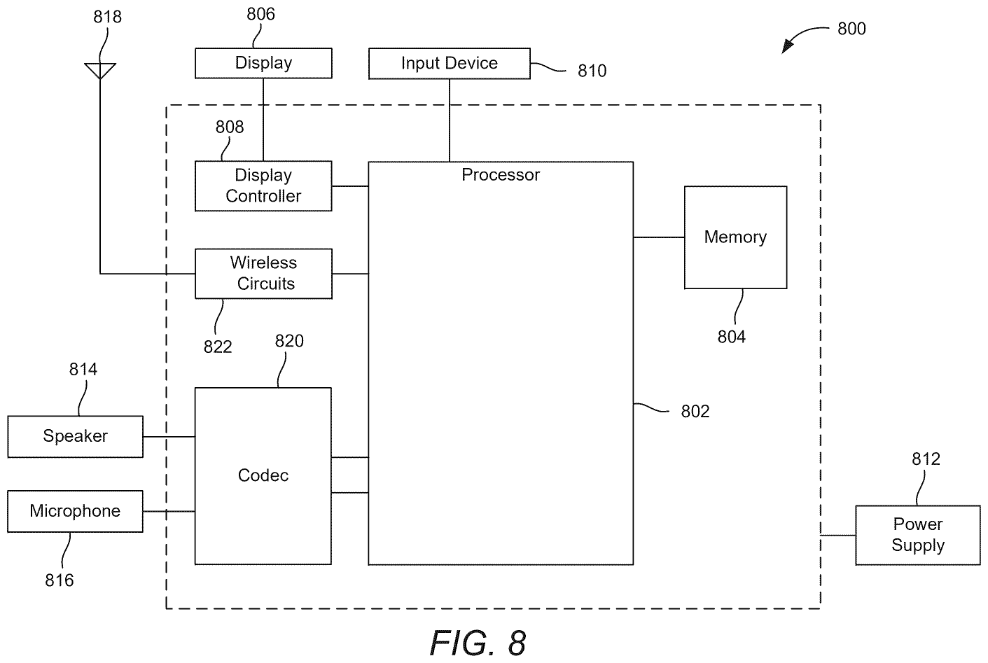

FIG. 8 illustrates a mobile device 800, according to aspects of the disclosure. In some aspects, the mobile device 800 may be implemented by including one or more IC devices manufactured based on the examples described in this disclosure.

In some aspects, mobile device 800 may be configured as a wireless communication device. As shown, mobile device 800 includes processor 802. Processor 802 may be communicatively coupled to memory 804 over a link, which may be a die-to-die or chip-to-chip link. Mobile device 800 also includes display 806 and display controller 808, with display controller 808 coupled to processor 802 and to display 806. The mobile device 800 may include input device 810 (e.g., physical, or virtual keyboard), power supply 812 (e.g., battery), speaker 814, microphone 816, and wireless antenna 818. In some aspects, the power supply 812 may directly or indirectly provide the supply voltage for operating some or all of the components of the mobile device 800.

In some aspects, FIG. 8 may include coder/decoder (CODEC) 820 (e.g., an audio and/or voice CODEC) coupled to processor 802; speaker 814 and microphone 816 coupled to CODEC 820; and wireless circuits 822 (which may include a modem, RF circuitry, filters, etc.) coupled to wireless antenna 818 and to processor 802.

In some aspects, one or more of processor 802, display controller 808, memory 804, CODEC 820, and wireless circuits 822 may include one or more IC devices including semiconductor structures manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

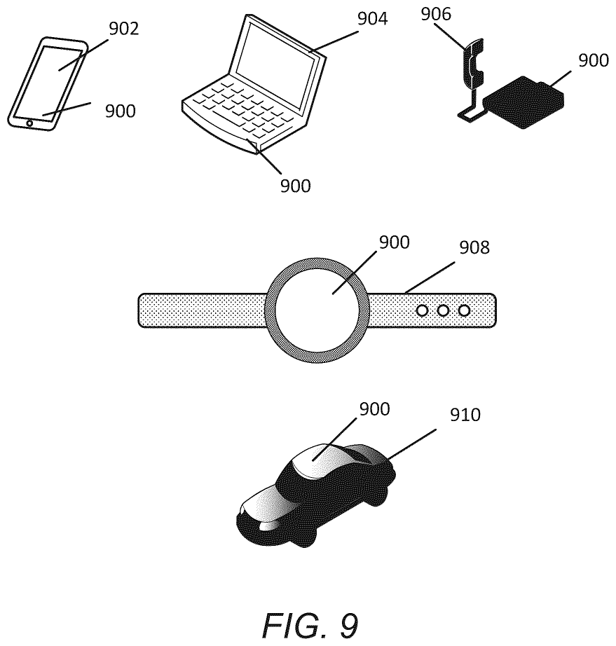

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 902, a laptop computer device 904, a fixed location terminal device 906, a wearable device 908, or automotive vehicle 910 may include a semiconductor device 900 (e.g., semiconductor structure 200, semiconductor structure 300, semiconductor structure 500) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A field effect transistor (FET) structure, comprising: a gate structure, disposed between a first source/drain (S/D) structure and a second S/D EPI structure, the gate structure comprising a channel structure and a vertical metal gate structure, the channel structure comprising a plurality of vertically-stacked, horizontal channels connecting the first S/D EPI structure to the second S/D EPI structure horizontally through the vertical metal gate structure that at least partially surrounds the plurality of channels, wherein at least one of the first S/D EPI structure and the second S/D EPI structure comprises a lower portion that extends vertically below a bottom surface of the vertical metal gate structure, the lower portion comprising sides and a bottom surface; a frontside inter-layer dielectric (ILD) layer disposed above the vertical metal gate structure, the first S/D EPI structure, and the second S/D EPI structure; and a backside ILD layer disposed below the vertical metal gate structure, the first S/D EPI structure, and the second S/D EPI structure.

Clause 2. The FET structure of clause 1, further comprising: a first coupling material disposed on the bottom surface of the lower portion of the first S/D EPI structure; and a first backside S/D contact (BSDC) extending vertically through the backside ILD layer and in contact with the first coupling material.

Clause 3. The FET structure of clause 2, wherein the first coupling material comprises silicide.

Clause 4. The FET structure of any of clauses 2 to 3, wherein the first coupling material is further disposed on at least one of the sides of the lower portion of the first S/D EPI structure.

Clause 5. The FET structure of any of clauses 1 to 4, further comprising a first etch stop material disposed on at least the bottom surface of the lower portion of the second S/D EPI structure.

Clause 6. The FET structure of clause 5, wherein the first etch stop material is further disposed on at least one of the sides of the lower portion of the second S/D EPI structure.

Clause 7. The FET structure of any of clauses 5 to 6, wherein the first etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

Clause 8. The FET structure of any of clauses 1 to 7, wherein the gate structure comprises a gate-all-around (GAA) structure.

Clause 9. A method for fabricating a field effect transistor (FET) structure, the method comprising: providing a gate structure, disposed between a first source/drain (S/D) structure and a second S/D EPI structure, the gate structure comprising a channel structure and a vertical metal gate structure, the channel structure comprising a plurality of vertically-stacked, horizontal channels connecting the first S/D EPI structure to the second S/D EPI structure horizontally through the vertical metal gate structure that at least partially surrounds the plurality of channels, wherein at least one of the first S/D EPI structure and the second S/D EPI structure comprises a lower portion that extends vertically below a bottom surface of the vertical metal gate structure, the lower portion comprising sides and a bottom surface; providing a frontside inter-layer dielectric (ILD) layer disposed above the vertical metal gate structure, the first S/D EPI structure, and the second S/D EPI structure; and providing a backside ILD layer disposed below the vertical metal gate structure, the first S/D EPI structure, and the second S/D EPI structure.

Clause 10. The method of clause 9, further comprising: providing a first coupling material disposed on the bottom surface of the lower portion of the first S/D EPI structure; and providing a first backside S/D contact (BSDC) extending vertically through the backside ILD layer and in contact with the first coupling material.

Clause 11. The method of clause 10, wherein the first coupling material comprises silicide.

Clause 12. The method of any of clauses 10 to 11, wherein the first coupling material is further disposed on at least one of the sides of the lower portion of the first S/D EPI structure.

Clause 13. The method of any of clauses 9 to 12, further comprising: providing a first etch stop material disposed on at least the bottom surface of the lower portion of the second S/D EPI structure.

Clause 14. The method of clause 13, wherein the first etch stop material is further disposed on at least one of the sides of the lower portion of the second S/D EPI structure.

Clause 15. The method of any of clauses 13 to 14, wherein the first etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

Clause 16. The method of any of clauses 9 to 15, wherein providing the gate structure comprises providing a gate-all-around (GAA) structure.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers.

Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A field effect transistor (FET) structure, comprising:
a gate structure, disposed between a first source/drain (S/D) epitaxial (EPI) structure and a second S/D EPI structure, the gate structure comprising a channel structure and a vertical metal gate structure, the channel structure comprising a plurality of vertically-stacked, horizontal channels connecting the first S/D EPI structure to the second S/D EPI structure horizontally through the vertical metal gate structure that at least partially surrounds the plurality of channels, wherein at least one of the first S/D EPI structure and the second S/D EPI structure comprises a lower portion that extends vertically below a bottom surface of the vertical metal gate structure, the lower portion comprising sides and a bottom surface;
a frontside inter-layer dielectric (ILD) layer disposed above the vertical metal gate structure, the first S/D EPI structure, and the second S/D EPI structure; and
a backside ILD layer disposed below the vertical metal gate structure, the first S/D EPI structure, and the second S/D EPI structure.

2. The FET structure of claim 1, further comprising:
a first coupling material disposed on the bottom surface of the lower portion of the first S/D EPI structure; and
a first backside S/D contact (BSDC) extending vertically through the backside ILD layer and in contact with the first coupling material.

3. The FET structure of claim 2, wherein the first coupling material comprises silicide.

4. The FET structure of claim 2, wherein the first coupling material is further disposed on at least one of the sides of the lower portion of the first S/D EPI structure.

5. The FET structure of claim 1, further comprising a first etch stop material disposed on at least the bottom surface of the lower portion of the second S/D EPI structure.

6. The FET structure of claim 5, wherein the first etch stop material is further disposed on at least one of the sides of the lower portion of the second S/D EPI structure.

7. The FET structure of claim 5, wherein the first etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

8. The FET structure of claim 1, wherein the gate structure comprises a gate-all-around (GAA) structure.

9. A method for fabricating a field effect transistor (FET) structure, the method comprising:
providing a gate structure, disposed between a first source/drain (S/D) epitaxial (EPI) structure and a second S/D EPI structure, the gate structure comprising a channel structure and a vertical metal gate structure, the channel structure comprising a plurality of vertically-stacked, horizontal channels connecting the first S/D EPI structure to the second S/D EPI structure horizontally through the vertical metal gate structure that at least partially surrounds the plurality of channels, wherein at least one of the first S/D EPI structure and the second S/D EPI structure comprises a lower portion that extends vertically below a bottom surface of the vertical metal gate structure, the lower portion comprising sides and a bottom surface;
providing a frontside inter-layer dielectric (ILD) layer disposed above the vertical metal gate structure, the first S/D EPI structure, and the second S/D EPI structure; and
providing a backside ILD layer disposed below the vertical metal gate structure, the first S/D EPI structure, and the second S/D EPI structure.

10. The method of claim 9, further comprising:
providing a first coupling material disposed on the bottom surface of the lower portion of the first S/D EPI structure; and
providing a first backside S/D contact (BSDC) extending vertically through the backside ILD layer and in contact with the first coupling material.

11. The method of claim 10, wherein the first coupling material comprises silicide.

12. The method of claim 10, wherein the first coupling material is further disposed on at least one of the sides of the lower portion of the first S/D EPI structure.

13. The method of claim 9, further comprising:
providing a first etch stop material disposed on at least the bottom surface of the lower portion of the second S/D EPI structure.

14. The method of claim 13, wherein the first etch stop material is further disposed on at least one of the sides of the lower portion of the second S/D EPI structure.

15. The method of claim 13, wherein the first etch stop material comprises at least one of titanium silicide (TiSi), silicon carbon nitride (SiCN), silicon carbon oxynitride (SiCON), aluminum nitride (AlN), an area-selective deposition (ASD) dielectric, or a silicon-germanium (SiGe) epitaxial layer.

16. The method of claim 9, wherein providing the gate structure comprises providing a gate-all-around (GAA) structure.
